(19) United States
(12) Patent Application Publication
(10) Pub. No.: US 2025/0212458 A1
(43) Pub. Date: Jun. 26, 2025

(54) BOTTOM-UP DIELECTRIC GAP-FILL FOR DEVICE ISOLATION DURING SOURCE/DRAIN EPITAXY IN CFET

(71) Applicant: Applied Materials, Inc., Santa Clara, CA (US)

(72) Inventors: Gregory COSTRINI, Flanders, NJ (US); Sai Hooi YEONG, San Jose, CA (US); Ashish PAL, San Ramon, CA (US); El Mehdi BAZIZI, San Jose, CA (US)

(73) Assignee: Applied Materials, Inc., Santa Clara, CA (US)

(21) Appl. No.: 18/391,015

(22) Filed: Dec. 20, 2023

(51) Int. Cl. H01L 29/423; H01L 21/8238; H01L 27/092; H01L 29/06; H01L 29/66; H01L 29/775; H01L 29/786

(52) U.S. Cl. CPC H10D 30/6735; H10D 30/014; H10D 30/43; H10D 30/6757; H10D 62/121; H10D 64/017; H10D 64/021; H10D 84/0172; H10D 84/038; H10D 84/85

(57) ABSTRACT

A system and method for fabricating a plurality of gate all around (GAA) complementary field effect transistors (CFETs). The fabrication method includes: fabricating a plurality of adjacent epitaxy layers, each of the plurality of epitaxy layers separated by a source/drain (S/D) canyon, each canyon defined by a sidewall of a first GAA CFET, and a sidewall of a second GAA CFET; depositing a dummy fill based on a target depth height into the S/D canyon; depositing a spacer cover on the sidewall of the first GAA CFET, and on the sidewall of the second GAA CFET; etching away the dummy fill to create a void in the S/D canyon; and depositing an isolator in the void at the target depth height.

### TECHNICAL FIELD

The present disclosure relates generally to gate all-around (GAA) devices, and specifically to complementary field effect transistor (CFET) GAA devices.

### BACKGROUND

The current generation of advanced logic devices are quasi planar architecture Gate All Around (GAA) devices that evolved from FinFET technology. GAA devices enable area scaling in several ways by essentially stacking the fin vertically, for example, in form of nanosheets. This enables better gate control, device performance and, in addition, reduces the footprint of the GAA device relative to FinFET, allowing to increase transistors per die.

The next generation of device architecture beyond GAA is being developed to stack GAA devices vertically, and is referred to as Complementary FET (or CFET) architecture. There are many process-related challenges to fabricate such devices. To enable stacking GAA devices vertically, the devices need to be isolated at several points in the fabrication process. The bottom and top device are of opposing polarities (e.g., NMOS and PMOS) and require separate epitaxy processes. The high aspect ratio of the CFET structure, which is a feature of the stacked devices, pushes conventional fabrication processes beyond the tolerance limit for the CFET structure.

It would therefore be advantageous to provide a solution that would overcome the challenges noted above, and further provide a solution that enables to isolate the devices for source/drain epitaxy, and improve process tolerance to meet the requirements of the CFET structure.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments, and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “some embodiments” or “certain embodiments” may be used herein to refer to a single embodiment or multiple embodiments of the disclosure.

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions.

In one general aspect, method may include fabricating a plurality of adjacent epitaxy layers, each of the plurality of epitaxy layers separated by a source/drain (S/D) canyon, each canyon defined by a sidewall of a first GAA CFET, and a sidewall of a second GAA CFET. Method may also include depositing a dummy fill based on a target depth height into the S/D canyon. Method may furthermore include depositing a spacer cover on the sidewall of the first GAA CFET, and on the sidewall of the second GAA CFET. Method may in addition include etching away the dummy fill to create a void in the S/D canyon. Method may moreover include depositing an isolator in the void at the target depth height. Other embodiments of this aspect include corresponding computer systems, apparatus, and computer programs recorded on one or more computer storage devices, each configured to perform the actions of the methods.

Implementations may include one or more of the following features. Method may include: fabricating an NP dummy filler on top of the plurality of adjacent epitaxy layers. Method may include: fabricating a second plurality of adjacent epitaxy layers on top of the NP dummy filler. Method where the second plurality of adjacent epitaxy layers include a polarity which is opposite to a polarity of the adjacent epitaxy layers. Method may include: etching away the NP dummy filler to create an NP void. Method may include: depositing an NP dielectric material in the NP void. Implementations of the described techniques may include hardware, a method or process, or a computer tangible medium.

In one general aspect, a GAA CFET circuit may include a plurality of adjacent epitaxy layers, fabricated such that each of the plurality of epitaxy layers are separated by a source/drain (S/D) canyon, each canyon defined by a sidewall of a first GAA CFET, and a sidewall of a second GAA CFET. GAA CFET circuit may also include a dummy fill deposited based on a target depth height into the S/D canyon. GAA CFET circuit may furthermore include a spacer cover deposited on the sidewall of the first GAA CFET, and on the sidewall of the second GAA CFET. GAA CFET circuit may in addition include an isolator deposited in a void at the target depth height, where the void is created by etching away the dummy fill in the S/D canyon. Other embodiments of this aspect include corresponding computer systems, apparatus, and computer programs recorded on one or more computer storage devices, each configured to perform the actions of the methods.

Implementations may include one or more of the following features. Circuit may include: an NP dummy filler fabricated on top of the plurality of adjacent epitaxy layers. Circuit may include: a second plurality of adjacent epitaxy layers fabricated on top of the NP dummy filler. Circuit where the second plurality of adjacent epitaxy layers include a polarity which is opposite to a polarity of the adjacent epitaxy layers. Circuit may include: an NP void created by etching away the NP dummy filler. Circuit may include: an NP dielectric material deposited in the NP void. Implementations of the described techniques may include hardware, a method or process, or a computer tangible medium.

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings.

FIG. 1 is an example diagram of an ideal multi-stage fabrication process of a gate all-around (GAA) complementary field effect transistor (CFET), utilized to describe an embodiment.

FIG. 2A is an example diagram of a first portion of a realistic multi-stage fabrication process of a GAA CFET, utilized to describe an embodiment.

FIG. 2B is an example diagram of a second portion of a realistic multi-stage fabrication process of a GAA CFET, utilized to describe an embodiment.

FIGS. 3A through 3D propose a process flow to fabricate more consistent CFET devices.

FIG. 3B is an example diagram of an isometric view of a GAA CFET device fabrication second step, implemented in accordance with an embodiment.

FIG. 3C is an example diagram of an isometric view of a GAA CFET device fabrication third step, implemented in accordance with an embodiment.

FIG. 3D is an example diagram of an isometric view of a GAA CFET device fabrication fourth step, implemented in accordance with an embodiment.

FIG. 4 is an example flowchart of a method for fabricating a GAA CFET device including epitaxy isolation, implemented in accordance with an embodiment.

FIG. 5 is an example schematic diagram of a system for fabricating a GAA CFET device, according to an embodiment.

### DETAILED DESCRIPTION

It is important to note that the embodiments disclosed herein are only examples of the many advantageous uses of the innovative teachings herein. In general, statements made in the specification of the present application do not necessarily limit any of the various claimed embodiments. Moreover, some statements may apply to some inventive features but not to others. In general, unless otherwise indicated, singular elements may be in plural and vice versa with no loss of generality. In the drawings, like numerals refer to like parts through several views.

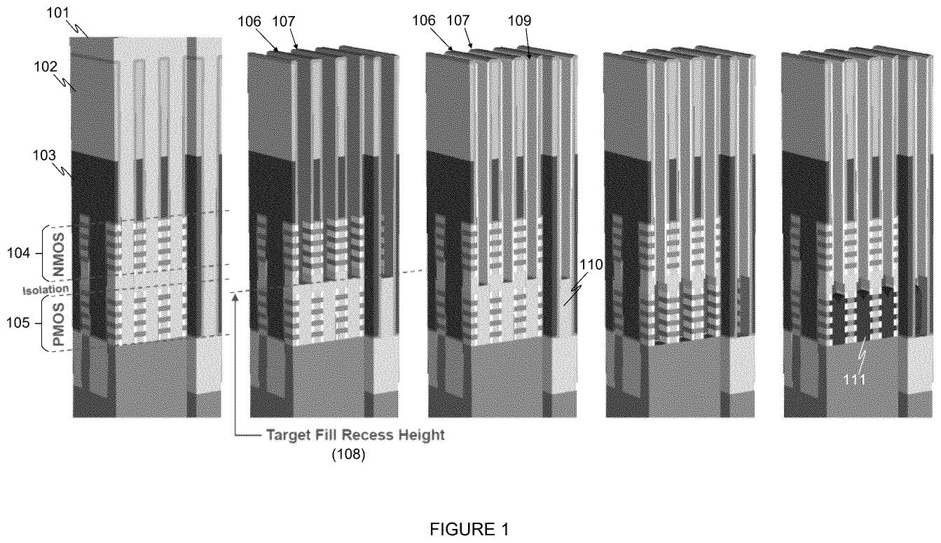

FIG. 1 is an example diagram of an ideal multi-stage fabrication process of a gate all-around (GAA) complementary field effect transistor (CFET), utilized to describe an embodiment. In an embodiment, a CFET device includes a fin, such as first fin 106 and second fin 107, which are separated by a source/drain (S/D) cavity.

According to an embodiment, a CFET includes a first device 105 having a first polarity, and a second device 104 having a second, opposite, polarity. For example, in an embodiment, the first device 105 is a PMOS device, and the second device 104 is an NMOS device.

In some embodiments, the first device 105 and the second device 104 are separated by an NP dielectric (NPDI). In an embodiment, an epitaxy layer of the first device 105 is deposited on a substrate, and a dummy filler is deposited thereon. In certain embodiments, an epitaxy layer of the second device 104 is deposited on top of the dummy filler. In an embodiment, the dummy filler is etched out, and an NP dielectric material is deposited in the S/D cavity to fill the NPDI void (i.e., the void created by etching out the dummy filler).

In an embodiment, the NPDI void is filled by iteratively depositing a dielectric material into the S/D cavity, etching away excess, and repeating the process until the NPDI void is filled. In an embodiment, this process is iterated two to four times. In some embodiments, deposition is performed by atomic layer deposition, and etching is performed by reactive ion etching.

In certain embodiments, a dummy polygate 103 is deposited on top of the epitaxy layers. In an embodiment, a hard mask 102 is deposited on top of the dummy polygate 103.

In some embodiments, a dummy fill 101 is deposited on the CFET devices, and the dummy fill 101 is deposited in the S/D cavity. According to an embodiment, the dummy fill is deposited in the S/D cavity between a first fin 106 and a second fin 107. In some embodiments, the dummy fill 101 is etched away to a target fill recess height 108.

In an embodiment, a cover spacer 109 is deposited on the sidewalls of the fins (e.g., fins 106 and 107). In an embodiment, the cover spacer 109 is deposited up to the height of the dummy fill 110. In certain embodiments, the dummy fill 110 is etched away after deposition of the cover spacer 109. In some embodiments, an insulator 111 is deposited in the S/D cavity after etching away the dummy fill 110.

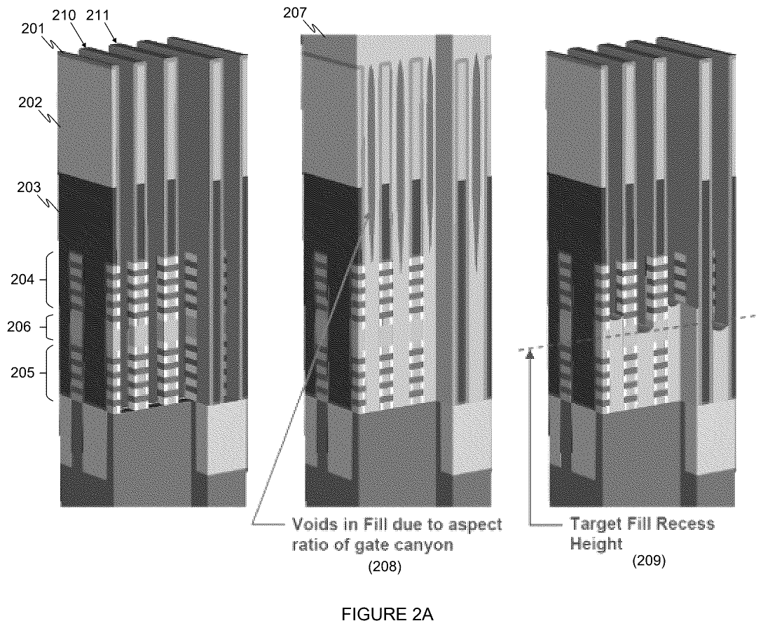

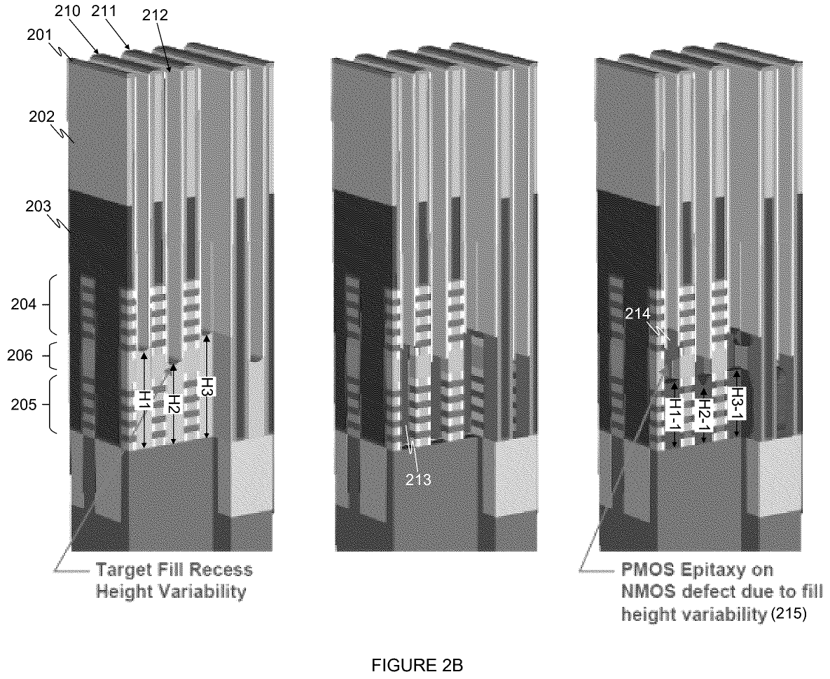

According to an embodiment, the process described above is an idealized version of the fabrication process for fabricating a CFET. As the idealized process is not a typical process, and certainly not one in high volume manufacturing, the following FIGS. 2A and 2B are directed to a fabrication process that is more typical of high volume manufacturing.

FIG. 2A is an example diagram of a first portion of a realistic multi-stage fabrication process of a GAA CFET, utilized to describe an embodiment. In an embodiment, a CFET includes a first device 205 having a first polarity, a second device 204 having a second, different, polarity, wherein the first device 205 and the second device 204 are separated by an NPDI fill 206. In an embodiment, the first device 205 and the second device 204 are covered by a dummy polygate 203 which is deposited on top of the stacked first device 205 and second device 204.

In some embodiments, a hard mask 202 is deposited on the dummy polygate 203. In an embodiment, a spacer 201 is deposited after the hard mask 202, for example on the sidewalls of the fins, such as first fin 210 and second fin 211.

In an embodiment, a dummy fill 207 is deposited in the S/D cavity between the fins (e.g., first fin 210 and second fin 211). In certain embodiments, deposition of the dummy fill 207 practically includes voids, such as void 208, which occur due to the aspect ratio of the gate canyon, which is the height of the fins vs. the distance between the fins.

In an embodiment, the dummy fill 207 is etched away to the target height 209. However, due to inconsistencies that are a result of void formations, there are inconsistencies in the actual height of the remaining dummy fill after the excess is etched off.

FIG. 2B is an example diagram of a second portion of a realistic multi-stage fabrication process of a GAA CFET, utilized to describe an embodiment. In some embodiments, a cover spacer 212 is deposited in the S/D cavity (e.g., the cavity between a first fin 210 and a second fin 211).

In some embodiments, a first dummy fill height H1 is higher than a second dummy fill height H2, where H2 is the height of the dummy fill between the first fin 210 and the second fin 211. In an embodiment, the height H3 of the dummy fill between the second fin 211 and the next fin is higher than H2. In some embodiments, H1, H2, and H3 are each substantially different heights.

Due the height difference of H1, H2, and H3, the deposition of the cover spacer 212 is done according to the height of the dummy fill of each S/D cavity. In an embodiment, the dummy fill is etched away, which results in voids in the S/D cavity, such as first void 213 which corresponds to the dummy fill height H1.

According to an embodiment, an insulator is deposited into the S/D cavities. In an embodiment, the height of the insulator fill varies based on the height of the dummy fill void and the subsequent depth of the cover spacer 212.

For example, according to an embodiment, the dummy fill height H1 results in a void which, when filled, results in an insulator fill having a height H1-1, and an insulator defect 214 which occurs to due to the fill height variability 215.

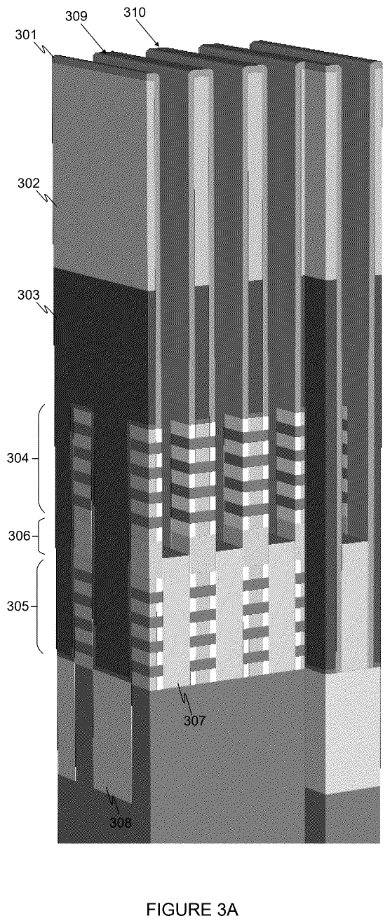

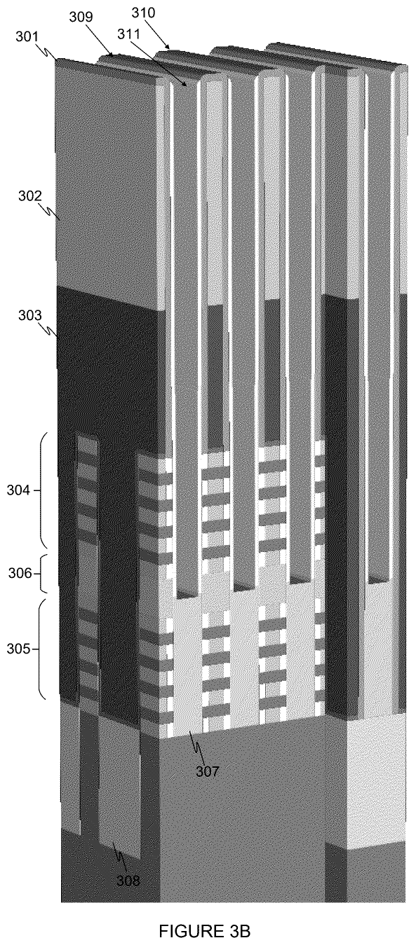

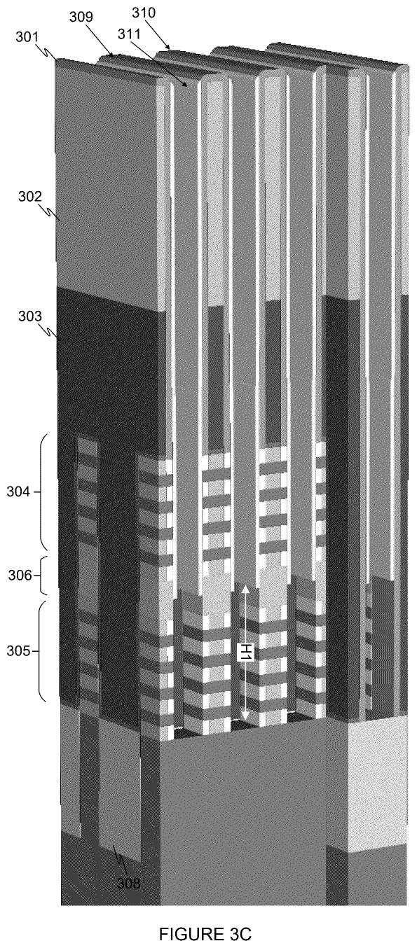

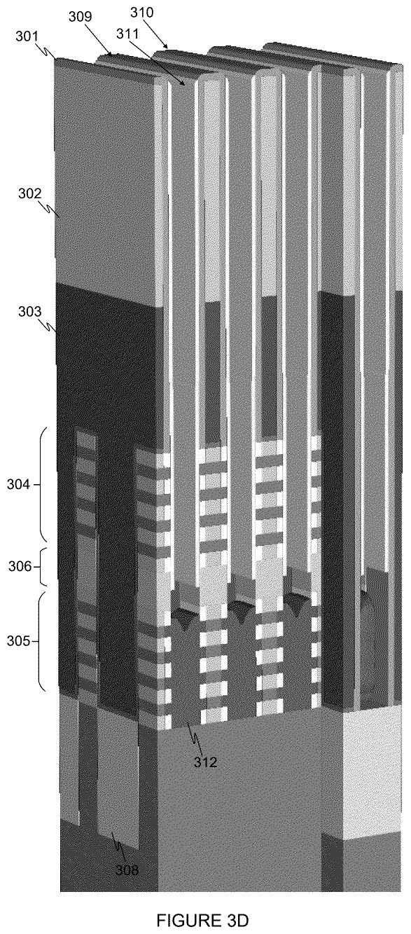

This process is problematic as devices with a degree of difference will inevitably function differently, fail differently, and are generally undesirable in high volume manufacturing of solid state devices. FIGS. 3A through 3D propose a process flow to fabricate more consistent CFET devices.

FIG. 3A is an example diagram of an isometric view of a GAA CFET device fabrication first step, implemented in accordance with an embodiment. In an embodiment, a gate all around complementary field effect transistor includes a plurality of devices. In some embodiments, a first portion of the devices have a first polarity, and a second portion of the devices have a second polarity.

For example, in an embodiment, the first portion are PMOS devices and the second portion are NMOS devices. In some embodiments, the plurality of devices are stacked with alternating polarity, such that a device of a first polarity is stacked above, beneath, or both, a device of a second, opposite, polarity.

As an example, according to an embodiment, a first device is a PMOS device, a second device stacked on top of the first device is an NMOS device, a third device stacked on top of the second device is a PMOS device, and a fourth device stacked on top of the third device is an NMOS device.

In some embodiments, the first device 305 is a PMOS device which is deposited on a silicon substrate. In certain embodiments, the first device 305 is separated by an NPDI 306 from a second device 304.

In an embodiment, the plurality of devices are covered by a dummy polygate 303, which in turn is covered by a hard mask 302. According to an embodiment, a spacer 301 is deposited after deposition of the hard mask 302.

In some embodiments, a dummy fill 307 is deposited in the S/D cavity between the fins, such as between a first fin 309 and a second fin 310. In an embodiment, the dummy fill 307 is filled up to the target fill height.

The previously described process has a tolerance that is proportional to the total height of the CFET structure, from the substrate up to the spacer 301. The previous process also requires a two-step process for this step, i.e., deposition and etching.

In contrast, the tolerance for a bottom-up fill process is proportional to the height of the target height, which is significantly lower than the total height of the CFET structure. This is especially true for multi-device CFET structures including four or more devices. It is therefore an improvement, both in terms of step reduction (i.e., no need to etch away a recess) and improved precision in the target fill height.

FIG. 3B is an example diagram of an isometric view of a GAA CFET device fabrication second step, implemented in accordance with an embodiment. According to an embodiment, after a dummy fill 307 is deposited in the S/D cavities, such as the S/D cavity between the first fin 309 and second fin 310, a cover spacer 311 is deposited on the sidewalls of each fin. In certain embodiments, deposition is performed utilizing atomic layer deposition techniques.

In an embodiment, depositing the cover spacer 311 on the fin sidewalls is performed to a depth which is controlled by the height of the dummy fill 307. It is therefore advantageous to have a precise fill method for the dummy fill 307 to reduce process error in fabrication of the cover spacer 311.

FIG. 3C is an example diagram of an isometric view of a GAA CFET device fabrication third step, implemented in accordance with an embodiment. In an embodiment, the dummy fill 306 of FIG. 3C is etched away which results in a void in each S/D cavity, having a height H1 which is the target fill height.

In certain embodiments, the void in the S/D cavity does not include a cover spacer 311, which is a primary purpose of depositing the dummy filler. In some embodiments, the dummy fill is etched away using reactive ion etching, wet etching techniques, dry etching techniques, combinations thereof, and the like.

FIG. 3D is an example diagram of an isometric view of a GAA CFET device fabrication fourth step, implemented in accordance with an embodiment. In an embodiment, a S/D cavity void is filled with an insulator 312, for example by deposition.

In an embodiment, the insulator 312 is an electric insulator, and deposition is performed utilizing, for example chemical vapor deposition (CVD), atomic layer deposition (ALD), various combinations thereof, and the like. As the voids are substantially uniform, the insulator 312 deposition is likewise substantially uniform.

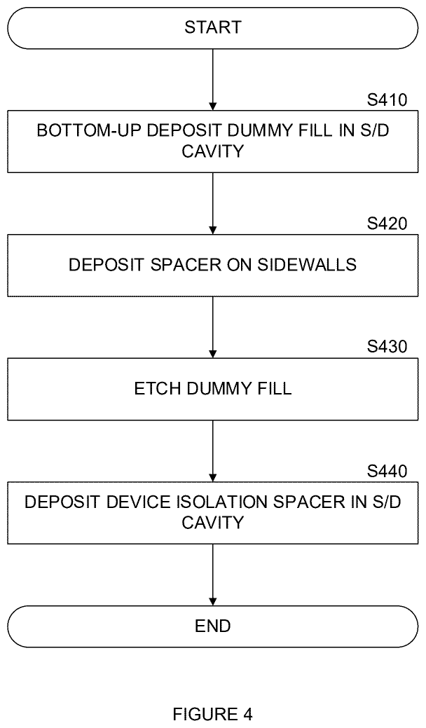

FIG. 4 is an example flowchart of a method for fabricating a GAA CFET device including epitaxy isolation, implemented in accordance with an embodiment. According to an embodiment, epitaxy isolation is crucial to performance of a GAA CFET device, and precise isolation by deposition of an insulator is desirable.

At S410, a dummy fill is deposited in S/D cavities. In an embodiment, each S/D cavity is defined between a fin of a first GAA CFET device, and a fin of a second GAA CFET device.

In some embodiments, the S/D cavity is fabricated by etching a channel through an epitaxy layer to effectively isolate GAA CFET devices. In an embodiment, a target height is predetermined for the dummy fill.

In an embodiment, the target height is proportional to the distance between the substrate and the height of the top epitaxy layer of the first device. In some embodiments, by depositing the dummy fill utilizing a target height, as opposed to a fill/recess process, the step of recessing is reduced. Additionally, in an embodiment, utilizing a target fill height is a more precise process to achieve uniform fill height, as the process tolerance is proportional to the target height, as opposed a process where the tolerance is proportional to the depth of the canyon (i.e., the height of the CFET).

At S420, a spacer is deposited. In an embodiment, a cover spacer is deposited on the sidewalls of each fin of the GAA CFETs. In certain embodiments, the cover spacer is an electrical insulator. In an embodiment, the cover spacer is deposited on the sidewalls by atomic layer deposition.

In an embodiment, the spacer is deposited up to the dummy fill. According to an embodiment, the dummy fill is deposited in order to deposit the cover spacer to a predetermined height.

At S430, the dummy fill is etched. In an embodiment, the dummy fill is etched away using reactive ion etching, wet etching, dry etching, a combination thereof, and the like. In an embodiment, the dummy fill is etched to fabricate a void, which does not include the spacer cover.

At S440, an insulator is deposited in the S/D void. In an embodiment, the insulator is deposited in a void between the S/D channel. In some embodiments, the insulator insulates between the epitaxy layers of the first device of a first CFET, and the epitaxy layers of the first device of a second CFET.

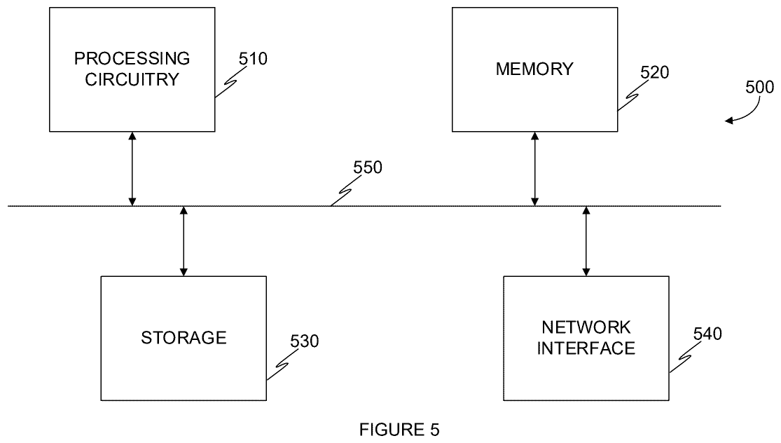

FIG. 5 is an example schematic diagram of a system 500 for fabricating a GAA CFET device, according to an embodiment. The system 500 includes, according to an embodiment, a processing circuitry 510 coupled to a memory 520, a storage 530, and a network interface 540. In an embodiment, the components of the system 500 are communicatively connected via a bus 550.

In certain embodiments, the processing circuitry 510 is realized as one or more hardware logic components and circuits. For example, according to an embodiment, illustrative types of hardware logic components include field programmable gate arrays (FPGAs), application-specific integrated circuits (ASICs), Application-specific standard products (ASSPs), system-on-a-chip systems (SOCs), graphics processing units (GPUs), tensor processing units (TPUs), Artificial Intelligence (AI) accelerators, general-purpose microprocessors, microcontrollers, digital signal processors (DSPs), and the like, or any other hardware logic components that are configured to perform calculations or other manipulations of information.

In an embodiment, the memory 520 is a volatile memory (e.g., random access memory, etc.), a non-volatile memory (e.g., read only memory, flash memory, etc.), a combination thereof, and the like. In some embodiments, the memory 520 is an on-chip memory, an off-chip memory, a combination thereof, and the like. In certain embodiments, the memory 520 is a scratch-pad memory for the processing circuitry 510.

In one configuration, software for implementing one or more embodiments disclosed herein is stored in the storage 530, in the memory 520, in a combination thereof, and the like. Software shall be construed broadly to mean any type of instructions, whether referred to as software, firmware, middleware, microcode, hardware description language, or otherwise. Instructions include, according to an embodiment, code (e.g., in source code format, binary code format, executable code format, or any other suitable format of code). The instructions, when executed by the processing circuitry 510, cause the processing circuitry 510 to perform the various processes described herein, in accordance with an embodiment.

In some embodiments, the storage 530 is a magnetic storage, an optical storage, a solid-state storage, a combination thereof, and the like, and is realized, according to an embodiment, as a flash memory, as a hard-disk drive, another memory technology, various combinations thereof, or any other medium which can be used to store the desired information.

The network interface 540 is configured to provide the system 500 with communication with, for example, a device for controlling fabrication of a semiconductor device, according to an embodiment.

It should be understood that the embodiments described herein are not limited to the specific architecture illustrated in FIG. 5, and other architectures may be equally used without departing from the scope of the disclosed embodiments.

The various embodiments disclosed herein can be implemented as hardware, firmware, software, or any combination thereof. Moreover, the software is preferably implemented as an application program tangibly embodied on a program storage unit or computer readable medium consisting of parts, or of certain devices and/or a combination of devices. The application program may be uploaded to, and executed by, a machine comprising any suitable architecture. Preferably, the machine is implemented on a computer platform having hardware such as one or more processing units (“PUs”), a memory, and input/output interfaces. The computer platform may also include an operating system and microinstruction code. The various processes and functions described herein may be either part of the microinstruction code or part of the application program, or any combination thereof, which may be executed by a PU, whether or not such a computer or processor is explicitly shown. In addition, various other peripheral units may be connected to the computer platform such as an additional data storage unit and a printing unit. Furthermore, a non-transitory computer readable medium is any computer readable medium except for a transitory propagating signal.

All examples and conditional language recited herein are intended for pedagogical purposes to aid the reader in understanding the principles of the disclosed embodiment and the concepts contributed by the inventor to furthering the art, and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

What is claimed is:

1. A method for fabricating a plurality of gate all around (GAA) complementary field effect transistor (CFET), comprising:
fabricating a plurality of adjacent epitaxy layers, each of the plurality of epitaxy layers separated by a source/drain (S/D) canyon, each canyon defined by a sidewall of a first GAA CFET, and a sidewall of a second GAA CFET;
depositing a dummy fill based on a target depth height into the S/D canyon;
depositing a spacer cover on the sidewall of the first GAA CFET, and on the sidewall of the second GAA CFET;
etching away the dummy fill to create a void in the S/D canyon; and
depositing an isolator in the void at the target depth height.

2. The method of claim 1, further comprising:
fabricating an NP dummy filler on top of the plurality of adjacent epitaxy layers.

3. The method of claim 2, further comprising:
fabricating a second plurality of adjacent epitaxy layers on top of the NP dummy filler.

4. The method of claim 3, wherein the second plurality of adjacent epitaxy layers include a polarity which is opposite to a polarity of the adjacent epitaxy layers.

5. The method of claim 3, further comprising:
etching away the NP dummy filler to create an NP void.

6. The method of claim 5, further comprising:
depositing an NP dielectric material in the NP void.

7. A gate all around (GAA) complementary field effect transistor (CFET) device circuit, comprising:
a plurality of adjacent epitaxy layers, fabricated such that each of the plurality of epitaxy layers are separated by a source/drain (S/D) canyon, each canyon defined by a sidewall of a first GAA CFET, and a sidewall of a second GAA CFET;
a dummy fill deposited based on a target depth height into the S/D canyon;
a spacer cover deposited on the sidewall of the first GAA CFET, and on the sidewall of the second GAA CFET; and
an isolator deposited in a void at the target depth height, wherein the void is created by etching away the dummy fill in the S/D canyon.

8. The circuit of claim 7, further comprising:
an NP dummy filler fabricated on top of the plurality of adjacent epitaxy layers.

9. The circuit of claim 8, further comprising:
a second plurality of adjacent epitaxy layers fabricated on top of the NP dummy filler.

10. The circuit of claim 9, wherein the second plurality of adjacent epitaxy layers include a polarity which is opposite to a polarity of the adjacent epitaxy layers.

11. The circuit of claim 9, further comprising:
an NP void created by etching away the NP dummy filler.

12. The circuit of claim 11, further comprising:
an NP dielectric material deposited in the NP void.
